(19) United States
(12) Patent Application Publication
(10) Pub. No.: US 2026/0130283 A1
(43) Pub. Date: May 7, 2026

(54) SEMICONDUCTOR PACKAGE

(71) Applicant: Samsung Electronics Co., Ltd., Suwon-si (KR)

(72) Inventors: Jisoo Hwang, Suwon-si (KR); SoYoung Kim, Suwon-si (KR)

(73) Assignees: Samsung Electronics Co., Ltd., Suwon-si (KR); Research & Business Foundation SUNGKYUNKWAN UNIVERSITY, Suwon-si (KR)

(21) Appl. No.: 19/216,006

(22) Filed: May 22, 2025

(30) Foreign Application Priority Data
Nov. 5, 2024 (KR) 10-2024-0155690

(51) Int. Cl. H01L 25/04; H01L 23/18; H01L 23/31; H01L 23/34; H01L 23/535; H01L 23/64

(52) U.S. Cl. CPC H10W 90/00; H10W 20/20; H10W 40/00; H10W 44/501; H10W 44/601; H10W 74/121; H10W 76/42; H10W 44/00

(57) ABSTRACT

Provided is a semiconductor package including a package substrate, a stacked structure mounted on the package substrate, and a heat dissipation structure mounted on the stacked structure, wherein the stacked structure includes a lower die, a passive device chip, a second upper die arranged apart from the passive device chip on the lower die, and a first upper die mounted on the passive device chip, and wherein the lower die includes a voltage control chip, the passive device chip includes a capacitor, and the package substrate includes an inductor.

### CROSS-REFERENCE TO RELATED APPLICATION

This application claims priority under 35 U.S. C. § 119 to Korean Patent Application No. 10-2024-0155690, filed on Nov. 5, 2024, in the Korean Intellectual Property office, the disclosure of which is incorporated by reference herein in its entirety.

### BACKGROUND

The inventive concept relates to a semiconductor package. The semiconductor package of the inventive concept may include an integrated voltage regulator (IVR) chip.

Voltage regulators (VRs) are widely used to regulate voltages in electronic devices, such as computers, servers, and smartphones. In some electronic devices, requirements such as a regulated voltage level and a current draw may be variously changed. Voltage regulators for small systems are designed based on the input current needs of those systems. Because it can be difficult or expensive to manufacture a voltage regulator integrated in a semiconductor chip, the voltage regulator is generally manufactured separately and disposed on a board for use by the semiconductor chip. Inductors and capacitors may also be required for the operation of the voltage regulator, and the inductors and the capacitors may also disposed on the board.

### SUMMARY

The inventive concept provides a semiconductor package having electrical stability and good heat dissipation characteristics with an improved degree of integration.

The technical solution and the benefits provided by the inventive concept are not limited to those mentioned above, and other benefits may be apparent to those of ordinary skill in the art in view of the following descriptions.

The inventive concept provides for a semiconductor package as described below.

According to an according to an aspect of the inventive concept, there is provided a semiconductor package including a package substrate, a stacked structure mounted on the package substrate, and a heat dissipation structure mounted on the stacked structure, wherein the stacked structure includes a lower die, a passive device chip, a second upper die arranged spaced apart from the passive device chip on the lower die, and a first upper die mounted on the passive device chip, and wherein the lower die includes a voltage control chip, the passive device chip includes a capacitor, and the package substrate includes an inductor.

According to another according to another aspect of the inventive concept, there is provided semiconductor package including a package substrate, a lower die mounted on the package substrate, a passive device chip mounted on the lower die, and the passive device chip including a capacitor, a second upper die mounted on the lower die, and the second upper die arranged adjacent to the passive device chip in a plan view, a first upper die mounted on the passive device chip, and a heat dissipation structure mounted on the first upper die and the second upper die, wherein the package substrate includes an inductor, and wherein the lower die includes a voltage control chip and an electrically connecting the voltage control chip and the first upper die to the second upper die.

According to another aspect of the inventive concept, there is provided a semiconductor package including a package substrate including an inductor, a lower die mounted on the package substrate, and wherein the lower die includes a voltage control chip arranged at a position adjacent to the inductor in a plan view, a passive device chip mounted on the lower die, and the passive device including a capacitor, a first upper die mounted on the passive device chip second upper die mounted on the lower die, and the second upper die arranged adjacent to the passive device chip in a plan view, the second upper die having an upper surface arranged at the same vertical level as an upper surface of the first upper die, a first sealing material sealing spaces between the passive device chip, the first upper die, and the at least one second upper die, a heat dissipation structure mounted on the first upper die and the second upper die, and a second sealing material covering an upper surface of the package substrate, the lower die, the passive device chip, the first upper die, second upper die, and the heat dissipation structure, wherein the first upper die is electrically connected to the second upper die by a bridge included inside the lower die.

### BRIEF DESCRIPTION OF THE DRAWINGS

Embodiments will be more clearly understood from the following detailed description taken in conjunction with the accompanying drawings in which:

FIG. 1 is a cross-sectional view of a semiconductor package according to an embodiment;

FIG. 2 is an enlarged cross-sectional view of a capacitor in a passive device chip in the semiconductor package of FIG. 1;

FIGS. 3A and 3B are an enlarged cross-sectional view and an enlarged perspective view of an inductor, in the semiconductor package of FIG. 1, respectively;

FIGS. 4 through 8 are cross-sectional views illustrating portions of a manufacturing process of a semiconductor package. according to embodiments; and

FIG. 9 is a cross-sectional view of a semiconductor package according to another embodiment.

### DETAILED DESCRIPTION OF THE EMBODIMENTS

Hereinafter, embodiments of the inventive concept are described in detail with reference to accompanying diagrams.

Because the invention may be embodied in many different forms, the inventive concept should not be construed as limited to the particular embodiments illustrated in the diagrams and described in detail. It should also be emphasized that the disclosure provides details of alternative examples, but such listing of alternatives is not exhaustive. Furthermore, any consistency of detail between various examples should not be interpreted as requiring such detail. In the description of the embodiments, certain details may be omitted when it is deemed that such descriptions may unnecessarily obscure the description of the embodiments.

Identical reference numerals are used for the same constituent devices in the drawings and duplicate descriptions thereof may be omitted.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed. Items described in the singular herein may be provided in plural, as can be seen, for example, in the drawings. Thus, the description of a single item that is provided in plural should be understood to be applicable to the remaining plurality of items unless context indicates otherwise.

As used herein, a semiconductor device may refer to any of the various devices such as shown in the figures, and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

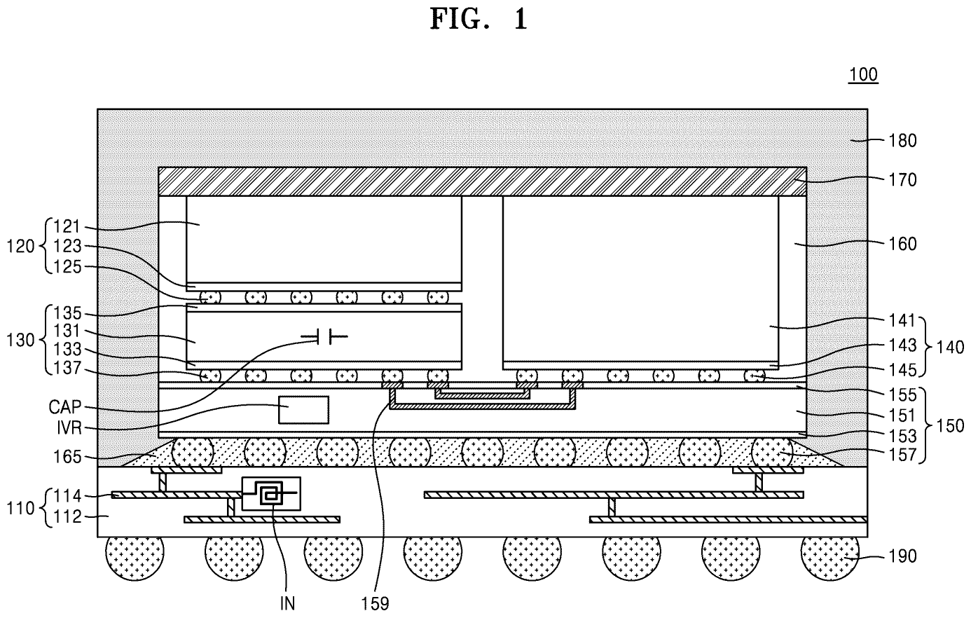

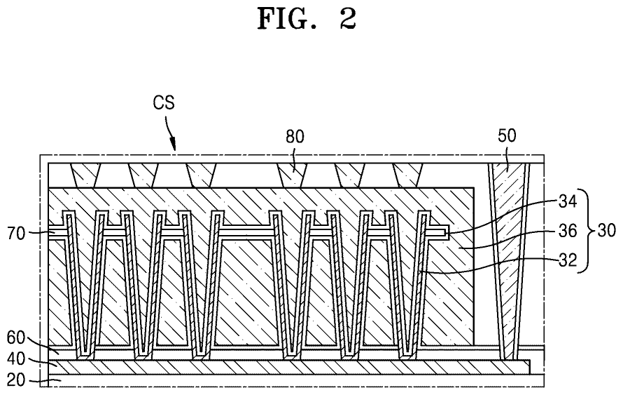

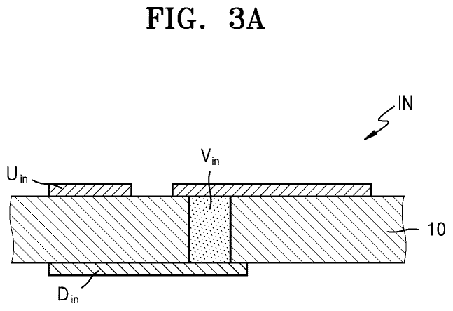

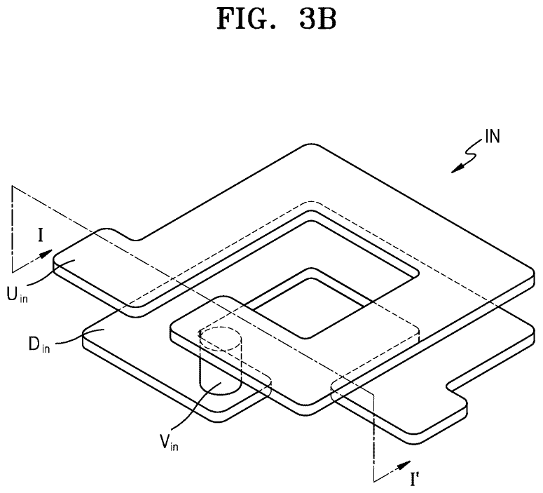

FIG. 1 is a cross-sectional view of a semiconductor package 100 according to an example embodiment. FIG. 2 is an enlarged cross-sectional view of a capacitor in a passive device chip in the semiconductor package of FIG. 1; FIGS. 3A and 3B are an enlarged cross-sectional view and an enlarged perspective view of an inductor in the semiconductor package of FIG. 1, respectively; and FIG. 3A corresponds to a cross-section taken along line I-I′ in FIG. 3B.

Referring to FIG. 1, the semiconductor package 100 may include a package substrate 110, a passive device chip 130, a first upper die 120, a second upper die 140, a lower die 150, a first sealing material 160, a heat dissipation structure 170, a second sealing material 180, and external connection terminals 190. The semiconductor package 100 may include an integrated voltage regulator (IVR) package including an inductor and a capacitor. As used herein, a passive device chip may be a semiconductor chip without any active components such as transistors.

The package substrate 110 may be a ceramic substrate, a printed circuit board (PCB), an organic substrate, an interposer substrate, etc. In addition, according to an embodiment, the package substrate 110 may also be an active wafer such as a silicon wafer. The package substrate 110 may include a substrate body layer 112, a wiring layer 114, and an inductor IN The substrate body layer 112 may include an insulating material, for example, a thermosetting resin such as an epoxy resin, or a thermoplastic resin such as polyimide, and may further include an inorganic filler. For example, the substrate body layer 112 may include a prepreg, an Ajinomoto build-up film (ABF), a flame retardant-4 (FR-4) resin, a Bismaleimide Triazine (BT) resin, or a photo imageable dielectric (PID) resin, and may further include an inorganic filler.

The wiring layer 114 may include a rewiring line and a via. The rewiring line may be formed as a multilayer structure and wiring lines between adjacent layers may be connected to each other by vias. The external connection terminals 190 may be arranged under a lower surface of the substrate body layer 112. The external connection terminals 190 may be respectively arranged under external connection pads and connected to the wiring layer 114 via the external connection pads. In addition, the external connection terminals 190 may be connected to dies (for example, first and second upper dies 120 and 140, passive device chips 130, or the like) mounted on the package substrate 110 by the wiring layer 114.

As illustrated in FIG. 1, the external connection terminals 190 may be arranged on a central region of a lower surface of the substrate body layer 112 corresponding to lower surfaces of the mounted dies, and the external connection terminals 190 may be arranged on an outer region of the lower surface of the substrate body layer 112 outside the central region. Consequently, the package substrate 110 may function to rearrange the external connection terminal 190 in a wider area than the area of the lower surfaces of the dies mounted via the wiring layer 114.

As illustrated in FIG. 1, the lower die 150, which includes a voltage control chip, may be arranged on the package substrate 110, the passive device chip 130 and the second upper die 140 may be arranged on the lower die 150, and the first upper die 120 may be arranged on the passive device chip 130.

The lower die 150 may be arranged on the package substrate 110. The lower die 150 may support the passive device chip 130, and the first and second upper dies 120 and 140. The lower die 150 may include a fourth body layer 151, a lower protection layer 153, an upper protection layer 155, fourth bumps 157, a bridge 159, and the voltage control chip IVR. The fourth body layer 151 may include a semiconductor substrate, an integrated circuit layer, an interlayer insulating layer, etc. In this case, the semiconductor substrate may be a silicon substrate. In addition, the integrated circuit layer may include a control circuit and a switching logic circuit as described below.

As used herein, a “bump” may be a connection bump for connection to another device. For example, a bump may be a solder ball.

The lower die 150 may perform various functions. For example, the lower die 150 may accommodate the voltage control chip IVR as described above. In some embodiments, the voltage control chip IVR may be a formed as a separate semiconductor chip distinct from the lower die 150 and then arranged in a recess of the lower die 150, or, in some embodiments, the voltage control chip IVR may be formed as a circuit of the lower die 150. In addition, as illustrated in FIG. 1, the lower die 150 may provide a signal path using the bridge 159 in addition to functioning as or accommodating the voltage control chip IVR.

The voltage control chip IVR may include a voltage control circuit for controlling a voltage. For example, the voltage control circuit may function as a voltage regulator VR. The voltage regulator VR may include a control circuit and a switching logic circuit. The control circuit may include a plurality of transistors for controlling the voltage, and the switching logic circuit may include at least two transistors for selecting a current path. The switching logic circuit may be connected to a capacitor CAP included in the passive device chip 130 and to an inductor IN included in the package substrate 110.

In general, the voltage regulator VR may include a DC-DC converter provided for raising or lowering an input voltage. Both an up converter and a down converter may change the input voltage using a switching operation and the capacitor CAP may reduce noise generated by the switching operation such as voltage ripple noise. In general, as the capacitance of the capacitor CAP increases, the current flowing through the converter circuit decreases and the noise reduction function may be improved by increasing the switching period.

In the semiconductor package 100 of the present embodiment, the voltage control chip IVR may be implemented as a semiconductor chip based on a silicon wafer. In addition, the voltage control chip IVR may be implemented as a structure in which a control circuit and a switching logic circuit are integrated into one semiconductor chip. This voltage control chip IVR may be manufactured in a compact structure by using a semiconductor process based on a silicon wafer.

In the semiconductor package 100 of the present embodiment, the voltage control chip IVR may further include logic devices in addition to the voltage regulator VR. The logic devices may be logic circuits, such as an AND, an OR, a NOT, and a flip-flop, and may perform various signal processing functions. For example, logic devices may perform various signal processing operations, such as an analog signal processing, an analog-to-digital (A/D) conversion processing, and control processing. In general, the logic devices may be included in a single logic chip, and the single logic chip may be referred to as a control chip, a process chip, a central processing unit (CPU) chip, an application processor (AP) chip, an application specific integrated circuit (ASIC) chip, or the like depending on the function. In addition, the logic chip may be implemented in a system on chip (SoC) structure by including logic devices of various functions together. In the semiconductor package 100 of the present embodiment, the voltage control chip IVR may include logic devices having various functions. Accordingly, the voltage control chip IVR may correspond to an SoC+IVR combination chip.

The passive device chip 130 may be arranged on the lower die 150, and may include a plurality of passive devices therein, such as the capacitors CAP. The passive device chip 130 may be formed based on a silicon wafer. For example, the passive device chip 130 may have a structure in which a plurality of capacitors CAP are integrated into a semiconductor chip. For example, the passive device chip 130 may include an integrated stacked capacitor (ISC) chip. In the case of the ISC chip, a large-capacity capacitor, for example, a capacitor of several to tens of nF, may be included. Accordingly, in the semiconductor package 100 of the present embodiment, the passive device chip 130 including the capacitor CAP may significantly contribute to the reduction of the voltage ripple noise in the switching operation of the voltage regulator VR.

The passive device chip 130 may include a second body layer 131, a lower protection layer 133, an upper protection layer 135, and second bumps 137. The capacitor CAP may be disposed in the second body layer 131. A description of the capacitor CAP in the second body layer 131 is given in more detail with reference to FIG. 2. The lower protection layer 133 and the upper protection layer 135 may be arranged on a lower surface and an upper surface of the second body layer 131, respectively, and may protect the capacitor CAP in the second body layer 131.

The first upper die 120 may include a first body layer 121, a lower protection layer 123, and first bumps 125. The first body layer 121 may include a semiconductor substrate, an integrated circuit layer, an interlayer insulating layer, etc. The first upper die 120 may be arranged on the passive device chip 130. In FIG. 1, the first upper die 120 and the passive device chip 130 are illustrated to completely overlap each other, but the embodiment is not limited thereto. In some other embodiments, a horizontal area of the first upper die 120 may be greater than a horizontal area of the passive device chip 130. In addition, in some other embodiments, the horizontal area of the first upper die 120 may also be less than the horizontal area of the passive device chip 130.

In some embodiments, a vertical direction thickness of the first upper die 120 may be greater than a vertical direction thickness of the passive device chip 130. In this case, heat dissipation characteristics of the first upper die 120 may be improved.

The second upper die 140 may include a third body layer 141, a lower protection layer 143, and third bumps 145. The third body layer 141 may include a semiconductor substrate, an integrated circuit layer, an interlayer insulating layer, etc. The second upper die 140 may be arranged spaced apart from the passive device chip 130 on the lower die 150. In some embodiments, the upper surface of the second upper die 140 may be arranged at the same vertical level as the upper surface of the first upper die 120.

The heat dissipation structure 170 may be arranged on the first upper die 120 and the second upper die 140. A lower surface of the heat dissipation structure 170 may be in contact with the first upper die 120 and the second upper die 140. In some embodiments, the heat dissipation structure 170 may be formed to have a thickness sufficient to efficiently dissipate heat generated by the first and second upper dies 120 and 140. The heat dissipation structure 170 may have a horizontal area large enough to cover both the upper surface of the first upper die 120 and the upper surface of the second upper die 140. As illustrated in FIG. 1, the heat dissipation structure 170 may be formed to have the same horizontal area as the lower die 150, but is not limited thereto.

The first sealing material 160 may seal the upper surface of the lower die 150, and the passive device chip 130, the first upper die 120, and the second upper die 140, and may prevent the passive device chip 130 and the first and second upper dies 120 and 140 from external physical and chemical damage.

The second sealing material 180 may seal the upper surface of the package substrate 110, and the lower die 150, the passive device chip 130, the first upper die 120, the second upper die 140, and the heat dissipation structure 170, and may prevent the mounting dies and the heat dissipation structure 170 from external physical and chemical damage.

The first and second sealing materials 160 and 180 may include an insulating material, such as, for example, a thermosetting resin such as an epoxy resin, a thermoplastic resin such as polyimide, an AFB, an FR-4 resin, a BT resin, etc. However, the materials of the first and second sealing materials 160 and 180 are not limited thereto.

The external connection terminals 190 may function to mount the semiconductor package 100 on an external system substrate or a main board. The external connection terminals 190 may include a conductive material, such as Cu, aluminum (Al), silver (Ag), tin (Sn), gold (Au), and solder. However, the material of the external connection terminal 190 is not limited thereto. In the semiconductor package 100 of the present embodiment, the external connection terminal 190 may include, for example, a solder ball.

Referring to FIG. 2, a capacitor structure CS may include a capacitor 30 or the capacitor CAP. The capacitor structure CS may be formed separately from the passive device chip 130 and then added to the passive device chip 130, or may be formed as an integral component of the passive device chip 130. The capacitor 30 may include a lower electrode 32, an upper electrode 36, and a dielectric layer 34. In addition, the capacitor structure CS may further include a plate electrode 40, a first through electrode 50, and a second through electrode 80. The capacitor structure CS may be arranged in the second body layer 131 of the passive device chip 130. The second body layer 131 may include a semiconductor substrate 20 and an insulating layer 60 on the semiconductor substrate 20. Due to the structure of the capacitor structure CS, the capacitor 30 may have a large capacitance of several to several tens of nF.

The plate electrode 40 may include a metal, metal oxide, metal nitride, or polysilicon. The first through electrode 50 may penetrate through the insulating layer 60 and be connected to the plate electrode 40. The second through electrode 80 may penetrate through a portion of the insulating layer 60 on the upper electrode 36 and may be connected to the upper electrode 36. A support 70 may be arranged between each of the capacitors 30.

Referring to FIGS. 3A and 3B, the inductor IN may, as described above, be arranged on the package substrate 110. The inductor IN may be formed separately from the package substrate 110 and then added to the package substrate 110, or may be formed as an integral component of the passive device chip 130. The inductor IN may include an upper wiring U_{IN}, a lower wiring D_{IN}, and an inductor via V_{IN}. The upper wiring U_{IN} and the lower wiring D_{IN} may include a portion of the wiring layer 114 of the package substrate 110. In some embodiments, the upper wiring U_{IN} and the lower wiring D_{IN} may be arranged with a body insulating layer 10 therebetween. The body insulating layer 10 may include an insulating material, for example, a thermosetting resin such as an epoxy resin, or a thermoplastic resin such as polyimide, and may further include an inorganic filler. In addition, the body insulating layer 10 may include, for example, prepreg, an ABF resin, an FR-4 resin, or a BT resin, and may further include an inorganic filler. In addition, the inductor via Vin may include a portion of a via (not illustrated) of the package substrate 110. In FIGS. 3A and 3B, the inductor IN may be implemented by using two layers of wirings and one inductor via, but the structure of the inductor IN is not limited thereto. For example, the inductor IN may also be implemented by using three or more layers of wiring and two or more inductor vias. In addition, the inductor IN may also have a shape in which a wiring extends from the center of the inductor IN to the outside of the inductor IN in a spiral shape, and an inductor via is arranged at the center thereof and/or at the outer end thereof.

The semiconductor package 100 of the present embodiment may have a structure in which the inductor IN and the capacitor CAP are included in a package structure together. In the semiconductor package 100 of the present embodiment, the inductor IN may be implemented in the package substrate 110, and the capacitor 30 may be implemented in the passive device chip 130 such as an integrated circuit chip arranged on an upper portion of the lower die 150 including the voltage control chip IVR. Accordingly, the semiconductor package 100 of the present embodiment may improve operation characteristics of the voltage control chip IVR, and reduce the size of the entire package.

For reference, a power management integrated circuit (PMIC) implemented on a board substrate may be called a voltage control chip IVR. To implement the voltage control chip IVR, the switching frequency of the voltage regulator VR may be increased and a close arrangement of an inductor and a capacitor may reduce voltage ripple due to high-speed switching. The semiconductor package 100 may correspond to a package in which the voltage control chip IVR is implemented with the inductor IN and the capacitor CAP arranged adjacent to the voltage control chip IVR in a package.

In addition, embodiments of the present disclosure may include a semiconductor package 100 having a structure in which an inductor and a capacitor arranged on a main board of a mobile device are integrated together in the semiconductor package 100. Accordingly, a semiconductor package 100 according to embodiments of the present disclosure may, in the mobile device, contribute to improving the characteristics of power integrity (PI) and reducing an area of the main board.

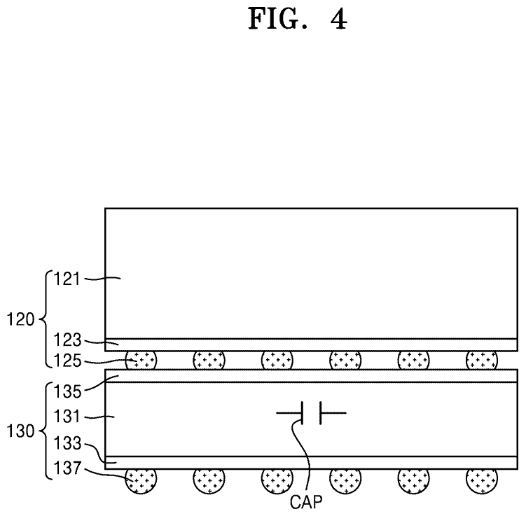

FIGS. 4 through 8 are cross-sectional views illustrating portions of a manufacturing process of the semiconductor package 100, according to embodiments.

Referring to FIG. 4, the first upper die 120 may be formed on the passive device chip 130. The first upper die 120 may be mounted on the passive device chip 130 by way of the first bumps 125.

The capacitor CAP may be included in the second body layer 131 of the passive device chip 130 and, although FIG. 4 illustrates that a horizontal area of the first upper die 120 arranged on the passive device chip 130 is the same as the horizontal area of the passive device chip 130, as described above, the horizontal area of the passive device chip 130 may be different from the horizontal area of the first upper die 120. In some embodiments, a vertical direction thickness of the first upper die 120 may be greater than a vertical direction thickness of the passive device chip 130.

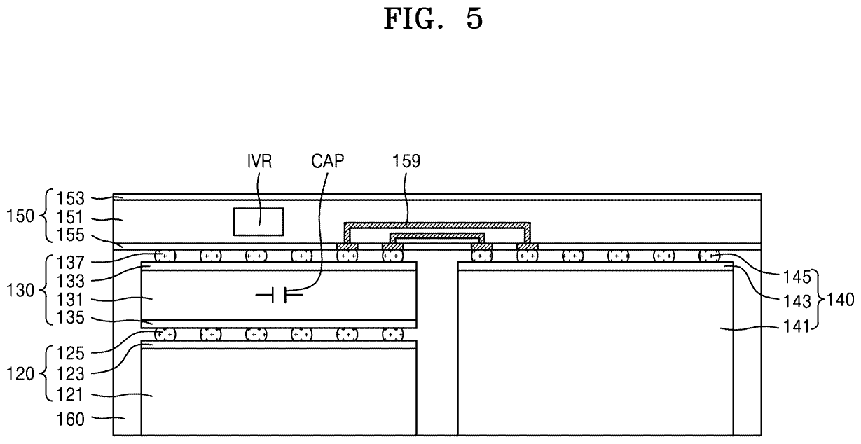

Referring to FIG. 5, the resultant product of FIG. 4 may be arranged on the lower die 150, and the second upper die 140, which is arranged on the lower die 150 and spaced apart from the resultant product of FIG. 4, may be formed. The resultant product of FIG. 4 may be connected to the lower die 150 via the second bumps 137, and the second upper die 140 may be connected to the lower die 150 via the third bumps 145.

The lower die 150 may include the voltage control chip IVR. The voltage control chip IVR may include a circuit for controlling a voltage therein (e.g., a voltage regulator VR). In addition, the resultant product of FIG. 4 may be electrically connected to the second upper die 140 via the bridge 159. For example, the lower die 150 may include the voltage control chip IVR for voltage control, and may, in addition, also include the bridge 159 for signal transmission to contribute to the improvement of the integration of the semiconductor package 100.

A horizontal cross-sectional area of the lower die 150 may be greater than the sum of horizontal cross-sectional areas of the resultant product of FIG. 4 and the second upper die 140. For example, after the passive device chip 130 and the first and second upper dies 120 and 140 are arranged on the lower die 150, a space may remain on the lower die 150 between the resultant product of FIG. 4 and the second upper die 140. The first sealing material 160, which covers all of the spaces between the lower die 150 and the passive device chip 130, between the lower die 150 and the first upper die 120, between the lower die 150 and the second upper die 140, and between the structure of the passive device chip 130 and the structure of the first upper die 120 and the second upper die 140, may then be formed.

The first sealing material 160 may fill all the spaces between the upper surface of the lower die 150 and the upper surfaces of the first and second upper dies 120 and 140. A vertical level of the upper surface of the first sealing material 160 may be the same as a vertical level of the upper surface of the first upper die 120 and a vertical level of the upper surface of the second upper die 140. For example, the upper surfaces of the first sealing material 160, the first upper die 120, and the second upper die 140 may all be coplanar.

Next, the lower die 150, on which the passive device chip 130, the first upper die 120, and the second upper die 140 are mounted, may be inverted so that the lower protection layer 153 faces upward as shown in FIG. 5.

Referring to FIG. 5 again, the voltage control chip IVR may be mounted at a location close to the passive device chip 130 in the lower die 150. For example, the voltage control chip IVR included in the lower die 150 and the capacitor CAP included in the passive device chip 130 may be formed, in a plan view, at a position where at least portions of the voltage control chip IVR and the capacitor CAP overlap or are adjacent to each other. When the voltage control chip IVR and the passive device chip 130 are arranged close to each other, this arrangement may be advantageous for electrical signal transmission.

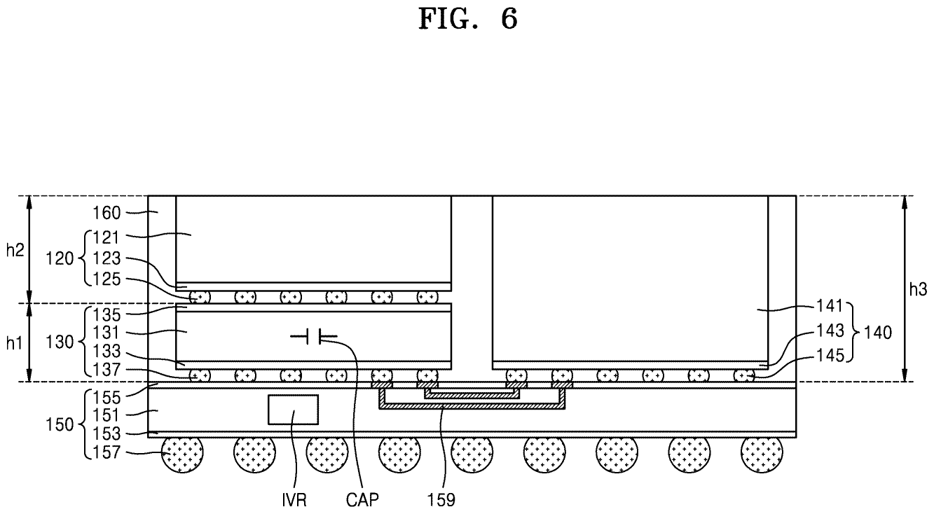

Referring to FIG. 6, the fourth bumps 157 may be attached onto the lower protection layer 153 of the lower die 150, and the resultant product of FIG. 5 may be inverted again so that the first and second upper dies 120 and 140 are arranged thereon as shown in FIG. 6.

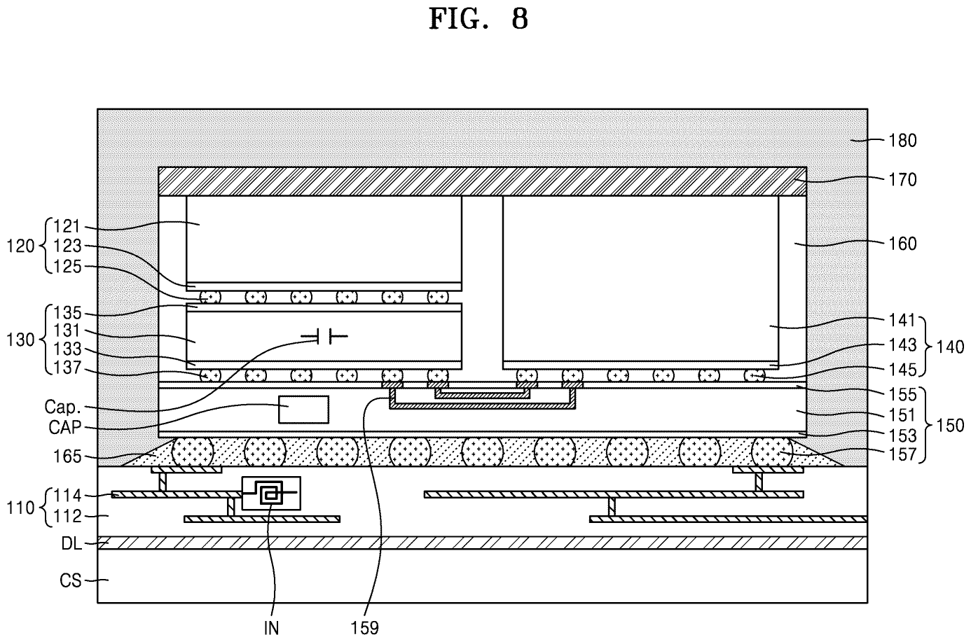

As illustrated in FIG. 6, the sum of a first height h1, which is the height from the upper surface of the upper protection layer 155 of the lower die 150 to the upper surface of the passive device chip 130, and a second height h2, which is the height from the upper surface of the upper protection layer 135 of the passive device chip 130 to the upper surface of the first upper die 120, may be the same as a third height h3, which is the height from the upper surface of the upper protection layer 155 of the lower die 150 to the upper surface of the second upper die 140. For example, the upper surfaces of the first and second upper dies 120 and 140 may be arranged on the same flat surface (e.g., the same plane), and thereafter, the heat dissipation structure 170 that is arranged on the first and second upper dies 120 and 140 may be in contact with all of the first and second upper dies 120 and 140 (refer to FIG. 8). In addition, as described above, in some embodiments, the second height h2 may be greater than the first height h1.

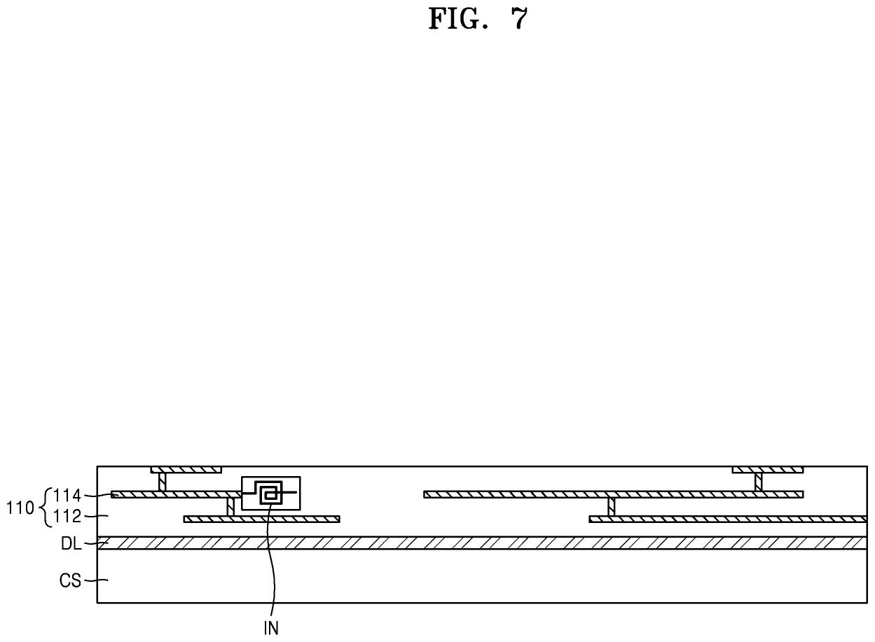

Referring to FIG. 7, after a carrier substrate CS is prepared, an adhesive insulating layer DL may be attached onto the carrier substrate CS and the package substrate 110 may be formed on the adhesive insulating layer DL.

The carrier substrate CS may include, for example, glass, silicon, or aluminum oxide. The adhesive insulating layer DL may include any material suitable for fixing the package substrate 110 to the carrier substrate CS. The adhesive insulating layer DL may include, for example, an adhesive tape in which an adhesion force is weakened by heat treatment, or in which an adhesion force is weakened by laser irradiation.

In some embodiments, the package substrate 110 may be formed on the adhesive insulating layer DL using a plating process or a deposition process.

The package substrate 110 may include the substrate body layer 112, the wiring layer 114, and the inductor IN. Because the voltage control chip (refer to IVR in FIG. 6) includes a voltage regulator VR therein, and the switching logic circuit included in the voltage regulator VR is connected to the capacitor (refer to CAP in FIG. 6) and the inductor IN, it may be beneficial for the inductor IN to be mounted on positions where the capacitor CAP and the voltage control chip IVR are to be disposed.

Referring to FIG. 8, the resultant product of FIG. 6 may be arranged on the package substrate 110 of FIG. 7.

After the heat dissipation structure 170 is mounted on the resultant product of FIG. 6, which is mounted on the package substrate 110, and the package substrate 110 is connected to the first upper die 120, the second upper die 140, the passive device chip 130, and the lower die 150 via the fourth bumps 157, an underfill material layer 165 may surround the fourth bumps 157, and the second sealing material 180 may seal spaces between the resultant product of FIG. 6, the heat dissipation structure 170, the underfill material layer 165, and the package substrate 110.

In some embodiments, the heat dissipation structure 170 may be formed on the first and second upper dies 120 and 140. The heat dissipation structure 170 may be formed to a thickness sufficient to disperse the heat generated by the first and second upper dies 120 and 140 to the outside.

In some embodiments, the underfill material layer 165 may be formed to surround fourth bumps 157 between the lower die 150 and the package substrate 110. The underfill material layer 165 may include, for example, epoxy resin formed using a capillary underfill method. In some embodiments, the underfill material layer 165 may include a non-conductive film (NCF).

In some embodiments, the second sealing material 180 may include an insulating material, for example, a thermosetting resin such as an epoxy resin, a thermoplastic resin such as polyimide, an AFB, an FR-4 resin, a BT resin, etc. The second sealing material 180 may function similarly to the first sealing material 160 and may also include the same components as the first sealing material 160, but materials included in the first sealing material 160 and the second sealing material 180 may be different from each other.

The semiconductor package 100 of FIG. 1 may be produced by removing the carrier substrate CS and forming external connection terminals 190 under the lower surface of the package substrate 110.

The external connection terminals 190 may include, for example, a solder ball, a conductive bump, a conductive paste, a ball grid array (BGA), a land grid array (LGA), a pin grid array (PGA), or a combination thereof.

The semiconductor package 100 may be formed using the processes described above, and in embodiments of a semiconductor package 100 according to the inventive concept, at least portions of the inductor IN included in the package substrate 110, the voltage control chip IVR included in the lower die 150, and the capacitor CAP included in the passive device chip 130 may overlap each other in a plan view (e.g., may overlap vertically), or may be arranged at adjacent positions. Because the lower die 150 including the voltage control chip IVR also includes the bridge 159 for signal transmission between the first and second upper dies 120 and 140, the degree of integration of a package may be improved.

In addition, the capacitor CAP included in the passive device chip 130 may function as an output capacitor of the voltage control chip IVR as well as a decoupling capacitor for a plurality of power sources. Accordingly, the arrangement of connection bumps attached to the back of the package (for example, the external connection terminals 190) may be relatively free (e.g., may not require connection bumps for connecting to a voltage control chip), and thus the electrical resistance of the package and reduction effect of inductance may be obtained by additionally secured connection bumps.

In addition, the heat dissipation characteristics of the package may also be improved by using the heat dissipation structure 170 arranged on the first and second upper dies 120 and 140.

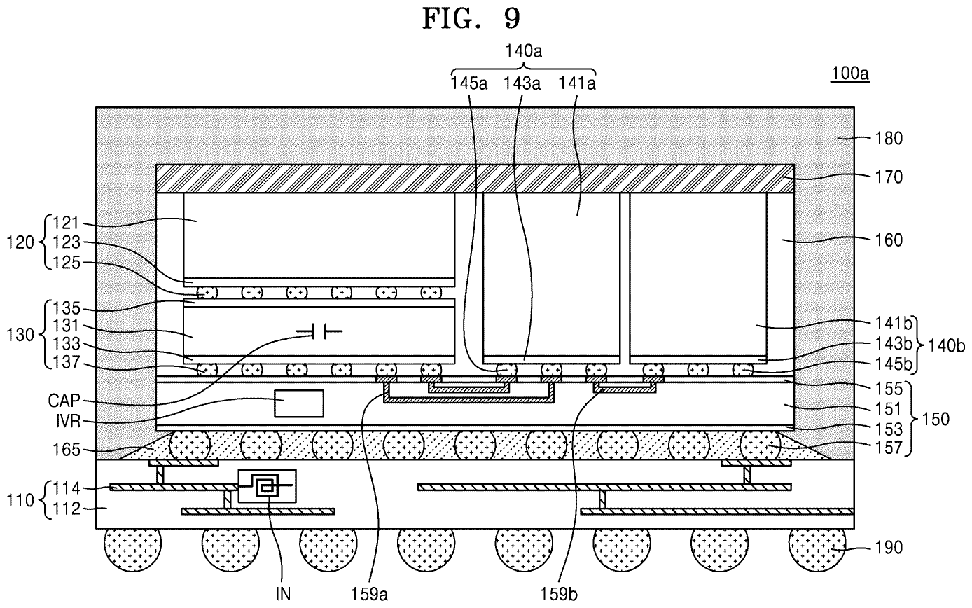

FIG. 9 is a cross-sectional view of a semiconductor package 100a according to another embodiment.

It will be understood that the semiconductor package 100a of FIG. 9 is not mutually exclusive with the semiconductor package 100 described with reference to FIGS. 1 through 8 and some components may be duplicated, and components having the same reference numerals may be the same or substantially the same. Hereinafter, duplicate descriptions of the same or substantially the same components are omitted, and differences from the descriptions of the semiconductor package 100 given with reference to FIGS. 1 through 8 are mainly described.

Referring to FIG. 9, unlike the semiconductor package 100 of FIG. 1 in which the passive device chip 130 and the first and second upper dies 120 and 140 are arranged on the lower die 150, the passive device chip 130, the first upper die 120, a second upper die 140a, and a third upper die 140b may be arranged on the lower die 150.

The first upper die 120 may be mounted on the passive device chip 130, and each of the second upper die 140a and the third upper die 140b may be arranged spaced apart from the passive device chip 130 on the upper surface of the lower die 150.

The second and third upper dies 140a and 140b may include third body layers 141a and 142b, lower protection layers 143a and 143b, and third bumps 145a and 145b, respectively. The third body layers 141a and 141b may include a semiconductor substrate, an integrated circuit layer, and an interlayer insulating layer, etc. The second and third upper dies 140a and 140b may have upper surfaces arranged at the same vertical level as the upper surface of the first upper die 120, and accordingly, the first, second, and third upper dies 120, 140a, and 140b may be in contact with the lower surface of the heat dissipation structure 170.

A first bridge 159a may connect the first upper die 120 to the second upper die 140a, and a second bridge 159b may connect the second upper die 140a to the third upper die 140b. However, this is an example illustration, and a bridge connecting the first upper die 120 to the third upper die 140b may be additionally included.

Like the semiconductor package 100 of FIG. 1, in the semiconductor package 100a of FIG. 9, the lower die 150 including the voltage control chip IVR may also perform electrical signal transmission using the bridge 159 to contribute to the improvement of the degree of integration of the package, and the capacitor CAP included in the passive device chip 130 may perform both a function of a decoupling capacitor and a function of the output capacitor of the voltage control chip IVR, and the heat dissipation characteristics of the package may also be improved by including the heat dissipation structure 170.

Although not illustrated, in addition to the semiconductor packages 100 and 100a of the inventive concept and the drawings, the inventive concept is not limited to the number of upper dies and the number of bridges shown and the number may be changed.

While the inventive concept has been particularly shown and described with reference to embodiments thereof, it will be understood that various changes in form and details may be made therein without departing from the spirit and scope of the following claims.

What is claimed is:

1. A semiconductor package comprising:
a package substrate;
a stacked structure mounted on the package substrate; and
a heat dissipation structure mounted on the stacked structure,
wherein the stacked structure comprises a lower die, a passive device chip, a second upper die arranged spaced apart from the passive device chip on the lower die, and a first upper die mounted on the passive device chip, and
wherein the lower die comprises a voltage control chip,
the passive device chip comprises a capacitor, and
the package substrate comprises an inductor.

2. The semiconductor package of claim 1, wherein the heat dissipation structure is mounted on the first upper die and the second upper die.

3. The semiconductor package of claim 1, wherein an upper surface of the first upper die is arranged at the same vertical level as an upper surface of the second upper die.

4. The semiconductor package of claim 1, wherein the lower die comprises a bridge therein.

5. The semiconductor package of claim 4, wherein opposite ends of the bridge are respectively connected to a connection bump of the passive device chip and a connection bump of the second upper die.

6. The semiconductor package of claim 1, further comprising, in the stacked structure, a first sealing material filling spaces between the passive device chip, the first upper die, and the second upper die.

7. The semiconductor package of claim 1,
further comprising, on the package substrate, a second sealing material covering an upper surface of the package substrate, the stacked structure, and the heat dissipation structure.

8. The semiconductor package of claim 7, wherein an upper surface of the second sealing material is disposed at a higher vertical level than an upper surface of the heat dissipation structure.

9. The semiconductor package of claim 1, wherein the voltage control chip and the inductor are arranged, in a plan view, at a position where at least portions thereof overlap the passive device chip.

10. The semiconductor package of claim 1, wherein a thickness of the passive device chip is less than a thickness of the first upper die.

11. The semiconductor package of claim 1, further comprising an external connection terminal under a lower surface of the package substrate.

12. The semiconductor package of claim 1, wherein the capacitor is a decoupling capacitor and an output capacitor of the voltage control chip.

13. The semiconductor package of claim 1, wherein neither a voltage control chip nor a capacitor is disposed on a lower surface of the package substrate.

14. A semiconductor package comprising:
a package substrate;
a lower die mounted on the package substrate;
a passive device chip mounted on the lower die, and the passive device chip including a capacitor;
a second upper die mounted on the lower die, and the second upper die arranged adjacent to the passive device chip in a plan view;
a first upper die mounted on the passive device chip; and
a heat dissipation structure mounted on the first upper die and the second upper die,
wherein the package substrate comprises an inductor therein, and
wherein the lower die comprises a voltage control chip and a bridge electrically connecting the voltage control chip and the first upper die to the second upper die.

15. The semiconductor package of claim 14,
wherein the inductor is disposed at a position where at least a portion of the inductor overlaps the passive device chip in a plan view of the package substrate, and
wherein the voltage control chip is disposed at a position where at least a portion of the voltage control chip overlaps the passive device chip in a plan view of the lower die.

16. The semiconductor package of claim 14, wherein an upper surface of the first upper die and an upper surface of the second upper die are in contact with a lower surface of the heat dissipation structure.

17. The semiconductor package of claim 14, wherein a thickness of the first upper die is greater than a thickness of the passive device chip.

18. The semiconductor package of claim 14, further comprising an external connection terminal disposed under a lower surface of the package substrate.

19. A semiconductor package comprising:
a package substrate including an inductor;
a lower die mounted on the package substrate, wherein the lower die includes a voltage control chip formed therein that is arranged at a position adjacent to the inductor in a plan view;
a passive device chip mounted on the lower die, and the passive device chip including a capacitor;
a first upper die mounted on the passive device chip;
a second upper die mounted on the lower die, and the second upper die arranged adjacent to the passive device chip in a plan view, the second upper die having an upper surface disposed at the same vertical level as an upper surface of the first upper die;
a first sealing material sealing spaces between the passive device chip, the first upper die, and the second upper die;
a heat dissipation structure mounted on the first upper die and the second upper die; and
a second sealing material covering an upper surface of the package substrate, the lower die, the passive device chip, the first upper die, the second upper die, and the heat dissipation structure,
wherein the first upper die is electrically connected to the second upper die by a bridge included inside the lower die.

20. The semiconductor package of claim 19, wherein the capacitor is a decoupling capacitor and an output capacitor of the voltage control chip.
